(19) United States
(12) Patent Application Publication
(10) Pub. No.: US 2019/0384147 A1
(43) Pub. Date: Dec. 19, 2019

(54) LIGHT DETECTING ELEMENT AND PROJECTION APPARATUS

(71) Applicant: Coretronic Corporation, Hsin-Chu (TW)

(72) Inventors: WEN-HAO CHU, Hsin-Chu (TW); YIN-NAN LAI, Hsin-Chu (TW); JENG-AN LIAO, Hsin-Chu (TW); CHEN-CHENG CHOU, Hsin-Chu (TW); TUNG-CHOU HU, Hsin-Chu (TW)

(21) Appl. No.: 16/382,219

(22) Filed: Apr. 12, 2019

(30) Foreign Application Priority Data
Jun. 13, 2018 (CN) 201820913010.8

(51) Int. Cl. G03B 21/16; H05K 1/18; H05K 1/02; G03B 21/00; G03B 21/20; G02B 26/00; G01D 5/34; G01D 5/26

(52) U.S. Cl. CPC G03B 21/16; H05K 1/181; H05K 1/0204; G03B 21/005; G03B 21/2006; H05K 2201/10151; G01D 5/342; G01D 5/264; H05K 2201/10121; H05K 2201/066; G02B 26/008

(57) ABSTRACT

A light detecting element for detecting rotations of a wheel is provided. The light detecting element includes a circuit board and an optical transceiver component. The circuit board has a first conductive layer and a first insulation layer. The first conductive layer has a first heat dissipation region, and the first insulation layer covers the first conductive layer and exposes the first heat dissipation region. The optical transceiver component is disposed on the first heat dissipation region and electrically connected to the circuit board. The optical transceiver component includes a light emitter and a light receiver, the light emitter is adapted to emit a light signal to the wheel, and the light receiver is adapted to receive the light signal reflected from the wheel. The invention further provides a projection apparatus having the light detecting element.

### CROSS-REFERENCE TO RELATED APPLICATION

THIS APPLICATION CLAIMS THE PRIORITY BENEFIT OF CHINA APPLICATION (CN201820913010.8 FILED ON 2018 Jun. 13). THE ENTIRETY OF THE ABOVE-MENTIONED PATENT APPLICATION IS HEREBY INCORPORATED BY REFERENCE HEREIN AND MADE A PART OF THIS SPECIFICATION.

### FIELD OF THE INVENTION

The invention relates to an electronic component, and more particularly to a light detecting element and a projection apparatus having the light detecting element.

### BACKGROUND OF THE INVENTION

In a projection apparatus having a single-piece light valve, a beam provided from a light source is transmitted to a filter wheel and/or a phosphor wheel, and different color lights are output in sequence from the filter wheel and/or the phosphor wheel. The light valve receives the color lights to generate different color image beams in sequence, thereby allowing a user to see color images formed by superimposing the different color image beams on a screen.

In order to correctly output the color images projected from the projection apparatus, the light valve needs to accurately operate in coordination with the color lights to correspondingly generate the different color image beams. Therefore, a detecting element is generally used to detect rotations of the filter wheel and the phosphor wheel so as to accurately control the output of each color light.

In addition, a housing is usually used to enclose the filter wheel and the phosphor wheel to prevent that the dust adheres to the filter wheel and the phosphor wheel. However, it is difficult for the filter wheel and the phosphor wheel to dissipate heat, which causes a higher surrounding temperature, and the detecting element may be affected by the high temperature and cannot operate normally, resulting in the projection apparatus outputting the color images incorrectly.

The information disclosed in this “BACKGROUND OF THE INVENTION” section is only for enhancement understanding of the background of the invention and therefore it may contain information that does not form the prior art that is already known to a person of ordinary skill in the art. Furthermore, the information disclosed in this “BACKGROUND OF THE INVENTION” section does not mean that one or more problems to be solved by one or more embodiments of the invention were acknowledged by a person of ordinary skill in the art.

### SUMMARY OF THE INVENTION

The invention provides a light detecting element to enhance the heat dissipation effect.

The invention provides a projection apparatus to correctly output color images.

Other objectives and advantages of the invention can be further understood from the technical features disclosed herein.

In order to achieve one or a part or all of the objectives or other objectives, one embodiment of the invention provides a light detecting element applicable to detect rotations of a wheel. The light detecting element includes a circuit board and an optical transceiver component. The circuit board has a first conductive layer and a first insulation layer. The first conductive layer has a first heat dissipation region, and the first insulation layer covers the first conductive layer and exposes the first heat dissipation region. The optical transceiver component is disposed on the first heat dissipation region and electrically connected to the circuit board. The optical transceiver component includes a light emitter and a light receiver, the light emitter is adapted to emit a light signal to the wheel, and the light receiver is adapted to receive the light signal reflected from the wheel.

In order to achieve one or a part or all of the objectives or other objectives, one embodiment of the invention provides a projection apparatus including an illumination system, a light valve and a projection lens. The illumination system includes a light source adapted to provide an illumination beam. The light valve is disposed on a transmission path of the illumination beam to convert the illumination beam into an image beam. The projection lens is disposed on a transmission path of the image beam to project the image beam. The illumination system further includes a wheel module, and the wheel module includes a wheel and the above-mentioned light detecting element. The wheel is disposed on the transmission path of the illumination beam to change a wavelength of the illumination beam, and the wheel has a light absorption mark. A cycle of each revolution of the wheel includes a light absorption time interval and a light reflection time interval. A light signal is absorbed by the light absorption mark during the light absorption time interval, and the light signal is reflected by the wheel to the light receiver during the light reflection time interval.

In the light detecting element of the embodiments of the invention, the optical transceiver component is disposed on the first heat dissipation region of the circuit board, and the first insulation layer is not located between the optical transceiver component and the first heat dissipation region. The heat generated by the optical transceiver component is able to directly transmit to the first heat dissipation region, and therefore the heat dissipation effect of the light detecting element can be enhanced. Because of the use of the above-mentioned light detecting element, the projection apparatus of the embodiments of the invention can avoid the problem that a prior art light detecting element cannot operate normally due to excessively high temperature, thus the color images can be correctly output.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a light detecting element according to an embodiment of the invention;

FIG. 2 is a schematic top view of a circuit board in FIG. 1;

FIG. 3 is a schematic bottom view of a light detecting element according to an embodiment of the invention;

FIG. 4 is a schematic side view of a light detecting element according to an embodiment of the invention;

FIG. 5 is a schematic block diagram of a projection apparatus according to an embodiment of the invention; and

FIG. 6 is a schematic cross-sectional view of a wheel module of a projection apparatus according to an embodiment of the invention.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

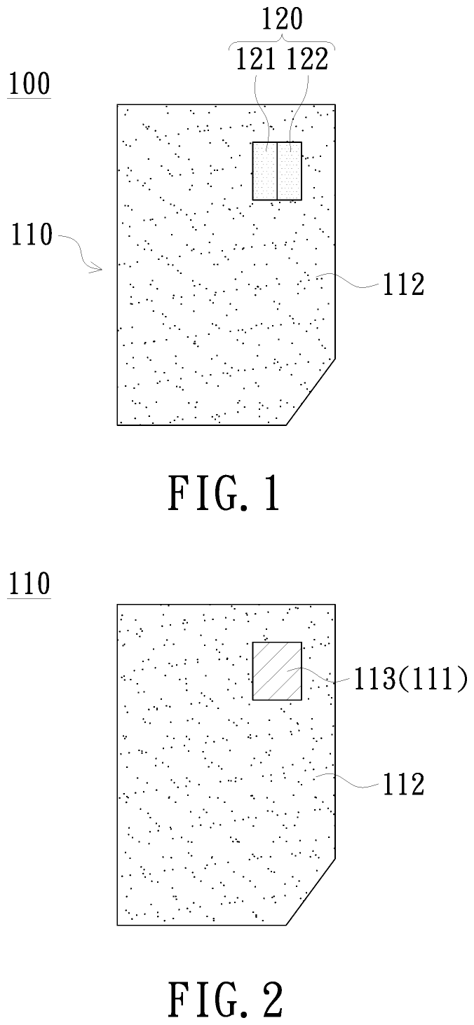

FIG. 1 is a schematic top view of a light detecting element according to an embodiment of the invention, and FIG. 2 is a schematic top view of a circuit board in FIG. 1. Please refer to FIGS. 1 and 2. The light detecting element 100 of the embodiment is adapted to detect a rotational position of a wheel, but is not limited to this use. The wheel is, for example, a filter wheel or a light wavelength conversion wheel (phosphor wheel) disposed in a projection apparatus, but is not limited to the wheel used by the projection apparatus. The light detecting element 100 includes a circuit board 110 and an optical transceiver component 120. The circuit board 110 has a first conductive layer 111 and a first insulation layer 112. The first conductive layer 111 has a first heat dissipation region 113, and the first insulation layer 112 covers the first conductive layer 111 and exposes the first heat dissipation region 113. The circuit board 110 of the embodiment has, for example, a plurality of conductive layers, and each of the conductive layers has a circuit pattern. The first conductive layer 111 is, for example, a conductive layer located at the uppermost layer. The circuit pattern of the first conductive layer 111 may further include a conductive circuit (not shown) in addition to the first heat dissipation region 113 for heat dissipation. The material of the conductive layers is, for example, copper or other conductive materials.

The optical transceiver component 120 is disposed on the first heat dissipation region 113 and electrically connected to the circuit board 110. That is, the first insulation layer 112 is not located between the optical transceiver component 120 and the first heat dissipation region 113. The optical transceiver component 120 is, for example, electrically connected to the above-mentioned conductive circuit of the first conductive layer 111 of the circuit board 110. The invention does not limit the manner in which the optical transceiver component 120 is electrically connected to the circuit board 110. In addition, the optical transceiver component 120 includes a light emitter 121 and a light receiver 122. The light emitter 121 is adapted to emit a light signal to the wheel, and the light receiver 122 is adapted to receive the light signal reflected from the wheel. In one embodiment, the light signal emitted by the light emitter 121 is, for example, infrared light, and the light receiver 122 is used to receive the infrared light reflected from the wheel, but the light signal is not limited to the infrared light.

In the embodiment, the first insulation layer 112 is not formed between the first heat dissipation region 113 and the optical transceiver component 120 to block the transfer of thermal energy, so that the heat dissipation efficiency of the light detecting element 100 can be enhanced. In addition, in order to further enhance the heat dissipation efficiency, a heat dissipation material layer (e.g., thermal grease) can be coated or a high-performance thermal pad can be disposed between the optical transceiver component 120 and the first heat dissipation region 113.

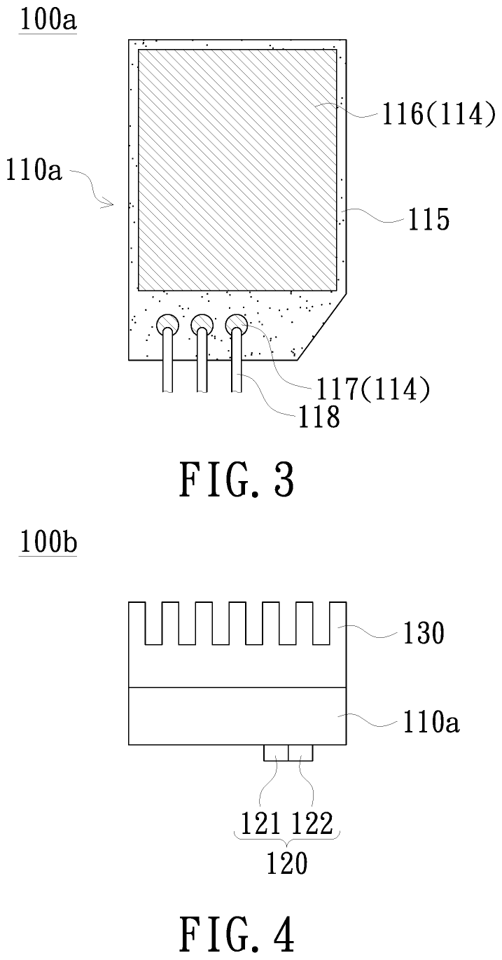

FIG. 3 is a schematic bottom view of a circuit board of a light detecting element according to an embodiment of the invention. Please refer to FIGS. 2 and 3. The light detecting element 100a of the embodiment is similar to the light detecting element 100 described above, and only the differences in structure will be described hereinafter. In the embodiment, the top view of the circuit board 110a is the same as FIG. 2. The circuit board 110a further includes a second conductive layer 114 and a second insulation layer 115 shown in FIG. 3 in addition to the first conductive layer 111 and the first insulation layer 112 shown in FIG. 2. The circuit board 110a has two surfaces opposite to each other (not labeled). The first conductive layer 111 and the first insulation layer 112 (shown in FIG. 2) are, for example, disposed on one surface of the circuit board 110a, and the second conductive layer 114 and the second insulation layer 115 are, for example, disposed on the opposite surface of the circuit board 110a. Furthermore, the first conductive layer 111 and the second conductive layer 114 are, for example, completely covered on the two surfaces of the circuit board 110a respectively. The first conductive layer 111 is disposed between the first insulation layer 112 and the second conductive layer 114, and the second conductive layer 114 is disposed between the first conductive layer 111 and the second insulation layer 115. Specifically, the second conductive layer 114 is, for example, the lowermost conductive layer of the circuit board 110a, and an insulation layer is formed between the first conductive layer 111 and the second conductive layer 114. Other conductive materials may also be disposed between the first conductive layer 111 and the second conductive layer 114. In addition, the material of the second conductive layer 114 may be the same as the material of the first conductive layer 111, and the material of the second insulation layer 115 may be the same as the material of the first insulation layer 112, and no redundant detail is to be given herein.

The second conductive layer 114 has a second heat dissipation region 116 and a plurality of pads 117, and the second insulation layer 115 covers the second conductive layer 114 and exposes the second heat dissipation region 116 and the pads 117. FIG. 3 is exemplified by including three pads 117, but the invention is not limited thereto. The pads 117 are used to electrically connect the transmission line 118 to transmit power and sensing signals. In addition, unused via holes (not shown) may be exposed in the second heat dissipation region 116. In one embodiment, the via holes can be blocked by, such as filling ink, resin, etc., to protect the circuit board 110a.

In the embodiment, as shown in FIG. 2, the optical transceiver component 120 is disposed on the first heat dissipation region 113. Since the second insulation layer 115 exposes the second heat dissipation region 116, the heat generated from the optical transceiver component 120 transmits from the first heat dissipation region 113 to the heat dissipation region 116, and the second heat dissipation region 116 dissipates heat to the outside air, so that the heat dissipation efficiency of the light detecting element 100a can be enhanced. In one embodiment, the area of the second heat dissipation region 116 is, for example, larger than the area of the second insulation layer 115 to provide a better heat dissipation effect. In addition, the size of the circuit board 110a can be enlarged to increase the area of the second heat dissipation region 116 on the surface of the circuit board 110a, thereby enhancing the heat dissipation efficiency. In addition, in one embodiment, a heat dissipator may be disposed on the second heat dissipation region 116. As shown in FIG. 4, the light detecting element 100b further includes a heat dissipator 130 disposed on the second heat dissipation region 116 (as shown in FIG. 3). The heat dissipator 130, for example, directly contacts the second heat dissipation region 116 to enhance the heat dissipation efficiency. The heat dissipator 130 of the embodiment is, for example, a heat sink. A heat dissipation material layer (e.g., thermal grease) may be further coated or a high-performance thermal pad may be disposed between the heat dissipator 130 and the circuit board 110a. Therefore, the heat generated from the optical transceiver component 120 transmits sequentially from the first heat dissipation region 113, the heat dissipation region 116 to the heat dissipator 130, and the heat dissipator 130 dissipates heat to the outside air.

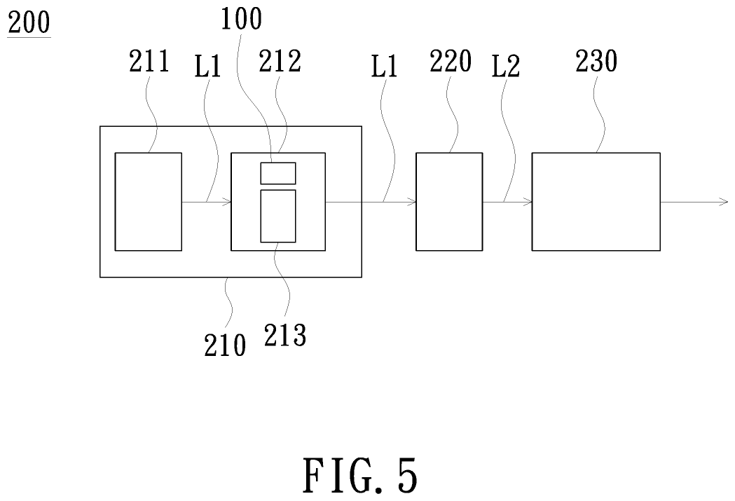

FIG. 5 is a schematic block diagram of a projection apparatus according to an embodiment of the invention. Please refer to FIG. 5. The projection apparatus 200 of the embodiment includes an illumination system 210, a light valve 220 and a projection lens 230. The illumination system 210 includes a light source 211 for providing an illumination beam L1. The light valve 220 is disposed on a transmission path of the illumination beam L1 to convert the illumination beam L1 into an image beam L2. The projection lens 230 is disposed on a transmission path of the image beam L2 to project the image beam L2 onto a screen to form an image. The light valve 220 can be a transmissive light valve or a reflective light valve, wherein the transmissive light valve may be a transmissive liquid crystal panel, and the reflective light valve may be a digital micro-mirror device (DMD) or a liquid crystal on silicon (LCOS) panel, but are not limited thereto. The projection lens 230 includes, for example, a single optical lens or a combination of a plurality of optical lenses with a diopter, such as various combinations of non-planar lenses including biconcave lens, biconvex lens, concave-convex lens, convex-concave lens, plano-convex lens, and plano-concave lens. In one embodiment, the projection lens 230 may also include a planar optical lens. The invention does not limit the form and type of the projection lens 230.

In addition, the illumination system 210 further includes a wheel module 212. The wheel module 212 includes a wheel 213 and the above-described light detecting element 100. The wheel 213 is disposed on the transmission path of the illumination beam L1 to change the wavelength of at least a portion of the illumination beam L1. The wheel 213 receiving the illumination beam L1 generates beams of different colors according to time sequence. The wheel 213 of the embodiment may be a filter wheel or a light wavelength conversion wheel, wherein the wavelength conversion material of the light wavelength conversion wheel may be fluorescence, phosphorescence, quantum dots or the like. In one embodiment, a quantity of the wheel module 212 may be two, such as a filter wheel and a light wavelength conversion wheel, respectively. Since the filter wheel and the light wavelength conversion wheel are common elements in projection apparatus and the structures and functions thereof are well known to those skilled in the art, no redundant detail is to be given herein.

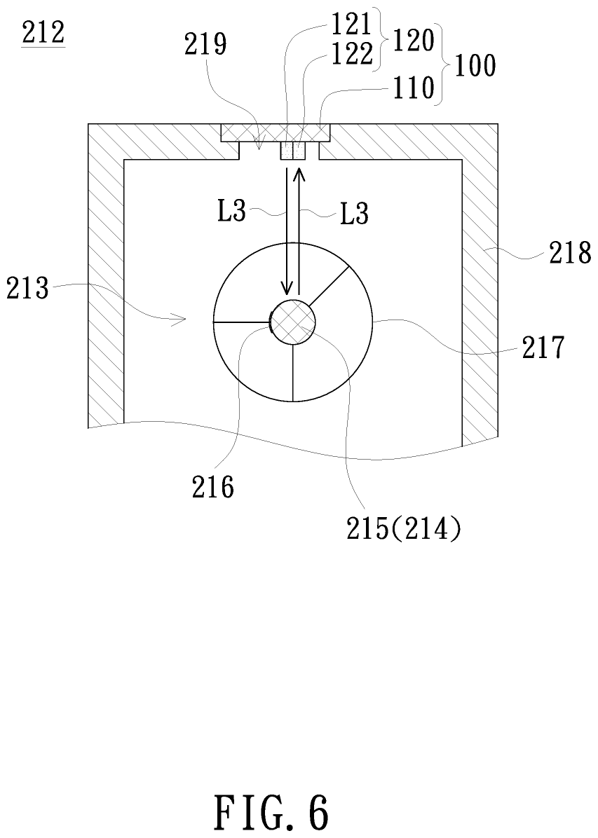

FIG. 6 is a schematic cross-sectional view of a wheel module of a projection apparatus according to an embodiment of the invention. Please refer to FIG. 6. The wheel 213 has a light absorption mark 216. The light absorption mark 216 of the embodiment is, for example, a black light absorbing material, but the invention is not limited thereto. The light absorption mark 216 is provided for absorbing the light signal L3 (e.g., infrared light) emitted by the light emitter 121 of the optical transceiver component 120. Specifically, the wheel 213 includes a motor 214, and the motor 214 has a rotating shaft 215. The light absorption mark 216 of the embodiment is, for example, disposed on the rotating shaft 215, but the invention does not limit the position of the light absorption mark 216 as long as it can match up with the light detecting element 100. In addition, the wheel 213 may further include a rotatable disc 217. The rotatable disc 217 is sleeved on the rotating shaft 215 of the motor 214, and the motor 214 is able to drive the rotatable disc 217 to rotate around the rotating shaft 215. When the wheel 213 is a filter wheel, the rotatable disc 217 includes a plurality of color filters of different colors. When the wheel 213 is a light wavelength conversion wheel, at least one light wavelength conversion material is disposed on the rotatable disc 217. The wheel module 212 of the embodiment further includes, for example, a housing 218. The housing 218 encloses the wheel 213 to provide a dustproof effect without affecting the rotating operation of the wheel 230. The housing 218 has an opening 219 disposed thereon. The opening 219 exposes the wheel 213. The light detecting element 100 is disposed at the housing 218, and the circuit board 110 of the light detecting element 100 completely covers the opening 219, so as to prevent dust from entering the housing 218. The optical transceiver component 120 disposed on the surface of the circuit board 110 faces the wheel 213.

In the embodiment, the light emitter 121 emits the light signal L3 toward the rotating shaft 215 for example, and the portion of the rotating shaft 215 where the light absorption mark 216 is not disposed can reflect the light signal L3 back to the light receiver 122. Therefore, as the motor 214 rotates, a cycle of each revolution of the wheel 213 includes a light absorption time interval and a light reflection time interval. The light signal L3 is absorbed by the light absorption mark 216 during the light absorption time interval, and the light signal L3 is reflected by the rotating shaft 215 of the wheel 213 to the light receiver 122 during the light reflection time interval. When the light receiver 122 does not receive the light signal L3, it is indicated that the light absorption mark 216 is rotated to a position corresponding to the light detecting element 120, so that the output of the color lights can be precisely controlled. In detail, the projection apparatus 200 may further include, for example, a control unit (not shown). The control unit is electrically connected to the light source 211, the light valve 220 and the wheel module 212 in FIG. 5. The control unit may control the time to output the color lights according to the sensing signals provided by the light detecting component 100, and thereby controlling the light valve 220 to generate the image beams of different colors according to the output of the color lights. Correspondingly, the color images projected from the projection apparatus 200 are able to be generated correctly.

Since the light detecting element 100 used in the embodiment has a better heat dissipation effect, the problem that the light detecting element 100 cannot operate normally due to the excessive high temperature can be avoided, and accordingly the color images projected from the projection apparatus 200 are able to be generated correctly. The light detecting element 100 of the embodiment can be replaced with the light detecting elements of the other embodiments mentioned above. The light detecting element 100a or 100b further enhances the heat dissipation effect. Particularly, when the light detecting element 100a shown in FIG. 3 is disposed at the housing 218 and covers the opening 219 (shown in FIG. 6), the second heat dissipation region 116 can directly dissipate heat generated by the light detecting element 100a to the outside of the housing 218, so as to improve the heat dissipation efficiency. Similarly, when the light detecting element 100b shown in FIG. 4 is disposed at the housing 218 and covers the opening 219 (shown in FIG. 6), the heat dissipator 130 disposed on the second heat dissipation region 116 can directly dissipate heat generated by the light detecting element 100b to the outside of the housing 218, so as to improve the heat dissipation efficiency.

In summary, in the light detecting element of the embodiments of the invention, the optical transceiver component is disposed on the first heat dissipation region of the circuit board, and the first insulation layer is not formed as a barrier between the optical transceiver component and the first heat dissipation region, and thus, the heat dissipation effect of the light detecting element can be enhanced. Because of the use of the above-mentioned light detecting element, the projection apparatus of the embodiment of the invention can avoid the problem that a prior-art light detecting element cannot operate normally due to excessively high temperature, thus the color images can be correctly outputted.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims. Furthermore, the terms such as the first conductive layer, the second conductive layer, the first insulation layer and the second insulation layer are only used for distinguishing various elements and do not limit the number of the elements.

What is claimed is:

1. A light detecting element adapted to detect rotations of a wheel, the light detecting element comprising a circuit board and an optical transceiver component, wherein
the circuit board comprises a first conductive layer and a first insulation layer, the first conductive layer has a first heat dissipation region, and the first insulation layer covers the first conductive layer and exposes the first heat dissipation region; and
the optical transceiver component is disposed on the first heat dissipation region and electrically connected to the circuit board, the optical transceiver component comprises a light emitter and a light receiver, the light emitter is adapted to emit a light signal to the wheel, and the light receiver is adapted to receive the light signal reflected from the wheel.

2. The light detecting element according to claim 1, wherein the circuit board further comprises a second conductive layer and a second insulation layer, the first conductive layer is disposed between the first insulation layer and the second conductive layer, the second conductive layer is disposed between the first conductive layer and the second insulation layer, the second conductive layer has a second heat dissipation region and a plurality of pads, and the second insulation layer covers the second conductive layer and exposes the second heat dissipation region and the pads.

3. The light detecting element according to claim 2, wherein an area of the second heat dissipation region is larger than an area of the second insulation layer.

4. The light detecting element according to claim 2, further comprising a heat dissipator disposed on the second heat dissipation region.

5. The light detecting element according to claim 1, wherein a thermal pad is disposed between the optical transceiver component and the first heat dissipation region.

6. A projection apparatus comprising an illumination system, a light valve and a projection lens, the illumination system comprising a light source, the light source being adapted to provide an illumination beam, the light valve being disposed on a transmission path of the illumination beam to convert the illumination beam into an image beam, and the projection lens being disposed on a transmission path of the image beam to project the image beam, wherein
the illumination system further comprises a wheel module, the wheel module comprises a wheel and a light detecting element, the wheel is disposed on a transmission path of the illumination beam to change a wavelength of the illumination beam, the wheel has a light absorption mark, and the light detecting element comprises a circuit board and an optical transceiver component; wherein
the circuit board comprises a first conductive layer and a first insulation layer, the first conductive layer has a first heat dissipation region, and the first insulation layer covers the first conductive layer and exposes the first heat dissipation region; and
the optical transceiver component is disposed on the first heat dissipation region and electrically connected to the circuit board, the optical transceiver component comprises a light emitter and a light receiver, the light emitter is adapted to emit a light signal to the wheel, a cycle of each revolution of the wheel comprises a light absorption time interval and a light reflection time interval, the light signal is absorbed by the light absorption mark during the light absorption time interval, and the light signal is reflected by the wheel to the light receiver during the light reflection time interval.

7. The projection apparatus according to claim 6, wherein the wheel comprises a motor, the motor has a rotating shaft, and the light absorption mark is disposed on the rotating shaft.

8. The projection apparatus according to claim 6, wherein the wheel module further comprises a housing for enclosing the wheel, the housing has an opening, the opening exposes the wheel, the light detecting element is disposed at the housing and covers the opening, and the optical transceiver component faces the wheel.

9. The projection apparatus according to claim 6, wherein the wheel comprises a filter wheel or a light wavelength conversion wheel.

10. The projection apparatus according to claim 6, wherein the circuit board further comprises a second conductive layer and a second insulation layer, the first conductive layer is disposed between the first insulation layer and the second conductive layer, the second conductive layer is disposed between the first conductive layer and the second insulation layer, the second conductive layer has a second heat dissipation region and a plurality of pads, and the second insulation layer covers the second conductive layer and exposes the second heat dissipation region and the pads.

11. The projection apparatus according to claim 10, wherein an area of the second heat dissipation region is larger than an area of the second insulation layer.

12. The projection apparatus according to claim 10, wherein the light detecting element further comprises a heat dissipator disposed on the second heat dissipation region.

13. The projection apparatus according to claim 10, wherein a thermal pad is disposed between the optical transceiver component and the first heat dissipation region.
